(19) United States
(12) Patent Application Publication
(10) Pub. No.: US 2016/0379828 A1
(43) Pub. Date: Dec. 29, 2016

(54) SILICON DOPING SOURCE FILMS BY ALD DEPOSITION

(71) Applicants: Anil U. Mane, Naperville, IL (US); Thomas E. Seidel, Palm Coast, FL (US); Michael I. Current, San Jose, CA (US); Alexander Goldberg, San Diego, CA (US); Jeffrey W. Elam, Elmhurst, IL (US)

(72) Inventors: Anil U. Mane, Naperville, IL (US); Thomas E. Seidel, Palm Coast, FL (US); Michael I. Current, San Jose, CA (US); Alexander Goldberg, San Diego, CA (US); Jeffrey W. Elam, Elmhurst, IL (US)

(21) Appl. No.: 15/191,389

(22) Filed: Jun. 23, 2016

Related U.S. Application Data
(60) Provisional application No. 62/185,100, filed on Jun. 26, 2015.

(51) Int. Cl. H01L 21/225; H01L 29/36; C23C 16/56; C23C 16/455; C23C 16/30; C23C 16/40

(52) U.S. Cl. CPC H01L 21/2255; C23C 16/30; C23C 16/403; C23C 16/56; C23C 16/45529; C23C 16/45553; H01L 29/36

(57) ABSTRACT

A conformal thermal ALD film having a combination of elements containing a dopant, such as boron (or phosphorus), and an oxide (or nitride), in intimate contact with a semiconductor substrate said combination having stable ambient and thermal annealing properties providing a shallow (less than ˜100 A) diffused (or recoil implanted) dopant, such as boron (or phosphorus) profile, into the underlying semiconductor substrate.

### RELATED APPLICATIONS

This is a NON PROVISIONAL of and claims priority to U.S. Provisional Application No. 62/185,100, filed Jun. 26, 2015, incorporated herein by reference.

### FIELD OF THE INVENTION

The present invention is related to the deposition of conformal surface coatings for doping applications for advanced silicon, germanium or other semiconductor devices, and in particular to an ALD layered structure and methods for making conformal surface coatings containing useful boron and phosphorus dopants.

### BACKGROUND

Films containing silicon dopants may be used in a variety of semiconductor device technologies. Especially as dimensions are reduced to the ˜10's of nanometers, the need for conformal dopant coatings becomes more important. In particular, dopants such as boron and phosphorus may be contained in ALD layered films and conformally placed on the surfaces of the fins of FinFETS, and either energetically recoiled or thermally diffused (or both) to affect transport of the dopants into the active volume of the semiconductor device. This affords a more uniform dopant distribution than may be obtained by direct ion implantation. See T. E. Seidel, M. D. Halls, A. Goldberg, J. W. Elam, A. Mane and M. I. Current “Atomic Layer Deposition of Dopants for Recoil Implantation in finFET Sidewalls,” IEEE Xplore, “20th International Conference on Ion Implantation Technology (IIT) 2014” (2014). In principle, the form of the dopant, e.g., boron, might be an elemental material or, but more advantageously as is shown, is composed of compound such as boron oxide within a stabilizing host matrix.

To our knowledge, no elemental processes are known for conformal, thermally deposited Atomic Layer Deposition (ALD) elemental boron or phosphorus, while in addition, ALD processes for boron oxide processes are not optimized. Boron films have been deposited by CVD (Sarubbi, F., et al., “Chemical Vapor Deposition of a-Boron Layers on Silicon for Controlled Nanometer Deep p+n Junction Formation” J. Electronic Materials, Vol 39, No.2, 2010) and boron oxide films by ALD. S. Consiglio, R. D. Clark, D. O'Meara, C. S. Wajda, K. Tapily, and G. J. Leusink Comparison of B2O3 and BN Deposited by Atomic Layer Deposition for Forming Ultra-shallow Dopant Regions by Solid State Diffusion” ALD-14 Kyoto Conference American Vacuum Society, Poster. However, the CVD process may not result in the desired conformal coating or process control, in addition a boron oxide may be susceptible to ambient instabilities. Boron oxide by itself may not be stable under the condition and atmosphere of a thermal diffusion processes.

Very few thermal ALD processes exist that are useful for making elemental materials. V. Miikkulainen et al., “Crystallinity of inorganic films grown by atomic layer deposition: Overview and general trends”, J. Appl. Phys. Revs. 113, 021301 (2013). In the review literature, it is found that elemental tungsten for example can be made using thermal ALD by using WF₆ and Si₂H₆. Since the Si₂H₆ removes the F terminations on W leaving Si—H terminations, and then WF₆ replaces the SiH by the byproduct SiFH₃, this has been called a replacement reaction. J. W. Klaus and S. M. George, “Solid material composing a thin metal film on its surface and methods for producing the same,” US patent: U.S. Pat. No. 6,958,174 B1, Oct. 25, 2005.

### SUMMARY OF THE INVENTION

The present inventors have recognized that what is needed is a technology that produces a deposited dopant containing film that is passivated, for example by the deposition of boron oxide within another stabilizing material such as Al₂O₃. If both boron-oxide and aluminum-oxide processes are by ALD, conformality is assured. Such ALD processes are described herein using preferred chemical reactions to deposit boron oxide in a thermally stable aluminum oxide matrix. This approach is differentiated from one where elemental boron or a boron oxide alone is capped by a protective, passivating deposited film. Related concerns occur for the deposition and thermal stability of phosphorous-rich ALD films.

A structure and processes are proposed using vapor phase chemically reacted, ALD layer(s) of boron incorporated into a metal oxide matrix. A layered film having a combination of elements containing a dopant, such as boron or phosphorus, and an oxide is obtained, said combination having stable ambient and thermal annealing properties for the purpose of providing a dopant, such as boron or phosphorus, by diffusion or by recoil implant combined with thermal annealing processes, into the underlying semiconductor (e.g., silicon, germanium or silicon-germanium) substrate.

A preferred embodiment for the process, in the case of boron-rich ALD films, uses sequential TMA—H₂O, with the H₂O last, followed by B₂F₄—H₂O. When this sequence is used, the ALD alternating process results in a reproducible steady state boron mass increase. This process produces a matrix of Al₂O₃ and B₂O₃. This is in contrast to an ALD B₂F₄—H₂O process alone or an ALD B₂F₄—Si₂H₆ replacement process alone, where the deposition per cycle is observed to become incrementally smaller with repeated cycles. In contrast, a continuing incremental deposition rate of a uniform deposition of BₓAl₂₋ₓO₃ is obtained by using alternate sequencing of ALD of TMA—H₂O and B₂F₄—H₂O on 12″ Si(100) wafer. See FIG. 1. The resultant matrix is a mixture of B₂O₃ and Al₂O₃.

The use of the halide B₂F₄ precursor is not unique. It is expected that several halides of boron may be used, e.g. BF₃, BCl₃, BBr₃, B₂Cl₄, or B₂Br₄. It is also possible to use organic dopant precursors instead of halides. However, the rationale for using B₂F₄ rather than BF₃, for example, is illustrated using first principles, DFT chemical reaction analysis. The nucleation reactions are energetically more favorable for B₂F₄ when compared with BF₃. See FIG. 2.

The choice of Al₂O₃ (as opposed to other metal oxides) in combination with B₂O₃ is preferred since Al is a p-type dopant, and under recoil implant processes, the Al would not counter dope the boron doping. For phosphorus doping, one can use Al₂O₃ safely only if the subsequent process is a thermal diffusion and not a recoil implant process. In both the boron dopant and the phosphorus dopant cases, the use of Al₂O₃ as the host matrix film instead of SiO2 may be practically advantageous, as ALD processes for Al2O3 are efficient and well developed relative to SiO₂. Additionally the binding energy of the Al—O is slightly higher than the Si—O bond, affording a more stable matrix under thermal processes. Additionally, the matrix may be composed of the oxide of the doping element combined with a nitride, such as SiN.

We have found by first principles Density Functional Theory (DFT) analysis that BF₃ or B₂F₄ with Si₂H₆ (analogous to the W replacement reaction) is highly endothermic and not suitable for thermal ALD of elemental boron.

These preferred chemistries allow a conformal deposition on the silicon surfaces of FinFETs. The thickness of boron oxide/aluminum oxide mixed film may be in the range 2-20 nm, although somewhat different thicknesses may be useful.

### BRIEF DESCRIPTION OF THE DRAWINGS

FIG. 1 Shows the increasing deposited mass for the deposition of a BₓAl₂₋ₓO₃ film by ALD sequencing of TMA—H₂O and B₂F₄—H₂O for 800 seconds.

FIG. 2 shows a comparison of enthalpies of BF₃ and B₂F₄ reacting on a hydroxylated and hydrided 100 cluster silicon surface model with better negative values for B₂F₄.

FIG. 3 shows the boron doping profiles in a silicon substrate for annealing temperatures of 700° C. and 825° C. respectively.

### DETAILED DESCRIPTION

One objective of the invention is a film, placed conformally on an underlying substrate, having a combination of elements containing a dopant, such as boron or phosphorus, and an oxide or nitride, said combination having stable ambient and thermal annealing properties for the purpose of providing a dopant concentrations in the underlying substrate at or near the dopant's solid solubility, such as boron or phosphorus, by diffusion into the underlying silicon substrate, (providing an ultra shallow doping profile at or below 100 A junction depth) Use of a kinetic recoil process for transport of dopants from the ALD film to the active semiconductor device volume relaxes some of the thermal stability requirements for the ALD film but retains some of the needs for film chemical stability against humid air reactions in a clean room ambient used for semiconductor device fabrication.

Another objective of the invention is a method using an ALD chemistry process to deposit boron containing film using B₂F₄—H₂O sequenced with TMA—H₂O, producing a BₓAl₂₋ₓO₃ layered film, said boron precursor allowing for alternate boron halide precursors.

Another objective of the invention is a method using an ALD chemistry process to deposit a phosphorus containing film using a phosphorus halide precursor and a silane precursor producing elemental phosphorus material layered within a ALD oxide or nitride matrix, or alternately an ALD chemistry process to deposit a phosphorus containing film using a phosphorus halide with an oxidant to deposit ALD phosphorus oxide material layered within a ALD oxide or nitride matrix.

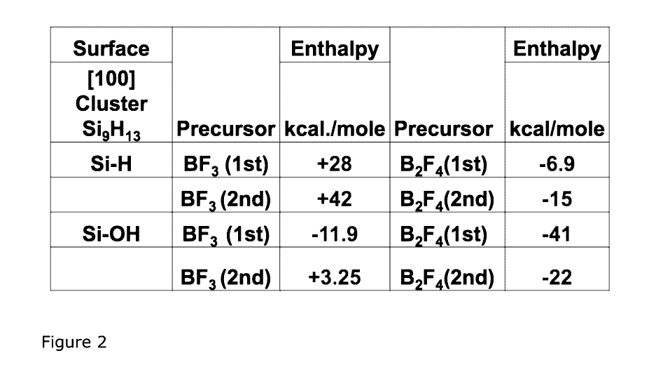

The enthalpy of reaction was calculated for the BF₃ vs B₂F₄ reacting groups using DFT (using the Schroedinger Co. (San Diego, Calif.) Jaguar™ program). A. D. Bochevarov et al.,“A High-Performance Quantum Chemistry Software Program with Strengths in Life and Materials Sciences”. Int. J. Quantum Chem. 113, (2013) 2110-2142. The silicon surfaces were modeled by a Si₉H₁₃ cluster model (K. Raghavachari and M. D. Halls, “Quantum chemical studies of semiconductor surface chemistry using cluster models” Molecular Physics 102 (2004) 381-393), where reactions are sequentially tested for enthalpy on two of the surface Si atoms of the cluster. These surface atoms may be either —H or —OH terminated. The results are significantly different for the two boron fluoride precursors. The results are shown in the table in FIG. 2.

To achieve the boron oxide layers, the silicon surface may be cleaned and prepared with dilute HF—H₂O wet chemistry and/or other processes known in the art, for example using a water-ozone process. M. L. Green et al., “Nucleation and growth of atomic layer deposited HfO₂ gate dielectric layers on chemical oxide (Si—O—H) and thermal oxide (SiO₂ or Si—O—N) underlayers”, J. Appl. Phys. 92, 7168 (2002). Chemical cleaning and surface nucleation processes might allow a direct attachment of a fractionally covered and terminated reactant to the silicon surface without using a bonding layer. The development of the concept described herein assumes that the [100] silicon surface is either —H or —OH terminated.

A starting point for the concepts described is the attempted use of the reference chemistry WF₆/Si₂H₆ (see Klaus and George, supra) to attempt to apply the same fluoride type of chemistry to form elemental boron, using BₓF_{y} precursors. The two precursors analyzed were BF₃ and B₂F₄. However, in each case the reactions: BF₃/Si₂H₆ and B₂F₄/Si₂H₆ were endothermic and not favorable for thermal ALD. Apparently, the bonding energy of the B—F bond is sufficiently strong that the replacement reaction is unfavorable. While it is found that B₂F₄ and H₂O are exothermic and favorable for making boron oxide, the fluoride chemistry (BₓF_{y}) is not useful for the silane ALD half reaction.

However, the simulation of these reactions is exothermic using BBr₃ and Si₂H₆ in a sequential ALD process. While the enthalpies are negative (exothermic) they are not very largely negative. This implies that the temperature for operation may require a relatively high range, e.g. 100-600° C. Additionally, other compounds of boron and bromine (e.g. B₂F₄) and other compounds of Si and hydrogen (e.g SiH₄) may be used; these are defined as derivatives of BBr₃ and derivative precursors of Si₂H₆. Included in the derivative set may be BCl₃ instead of BBr₃, to be used with the silanes.

The combination of using precursors of B₂F₄ and H₂O for the formation of ALD boron oxide has, to our knowledge not been previously described. The BF₃ and B₂F₄ precursors reacting with H₂O were analyzed using DFT and it was found that the combination B₂F₄/H₂O was much more reactive and exothermic than BF₃/H₂O. See FIG. 2. Because the enthalpies are large negative values, the ALD temperatures may be relatively low, e.g. ˜100° -300° C., but may be successful outside this range, as well. An ALD chemistry for an improved process to deposit boron oxide using B₂F₄ with water is described. Other precursors in the BₓFₓ (e.g. BF₃) and HₓO_{y} (e.g. H₂O₂) class may also be used; these are defined as derivative precursors.

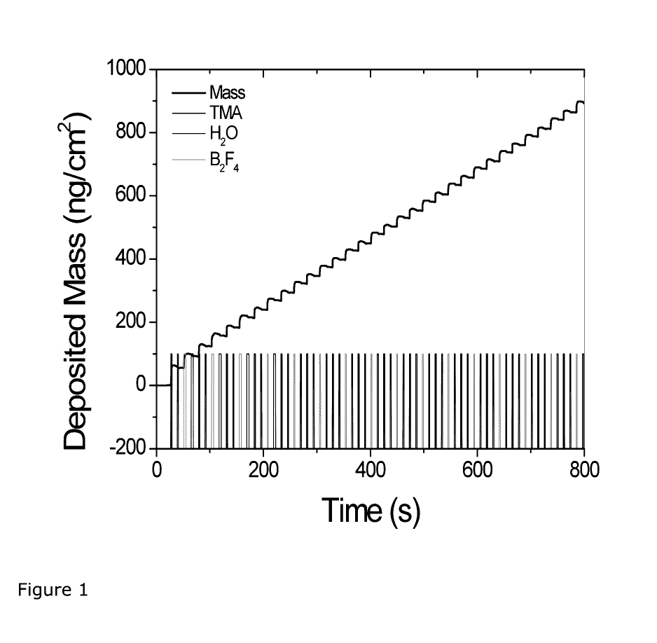

Considering the above, a preferred embodiment for the process uses sequential TMA—H₂O, with the H₂O last, followed by B₂F₄—H₂O. When this sequence is used, the ALD alternating process resulted in a reproducible steady state boron mass increase. This process produces a matrix of Al₂O₃ and B₂O₃. This is in contrast to an ALD B₂F₄—H₂O process alone or an ALD B₂F₄—Si₂H₄ replacement process alone, where the deposition per cycle is observed to become incrementally smaller with repeated cycles. In contrast, a continuing incremental deposition rate of a uniform deposition of BxAl2—xO3 is obtained by using alternate ALD of TMA—H₂O and B₂F₄—H₂O on 12″ Si(100) wafer. See FIG. 1. The resultant matrix is a mixture of Al₂O₃ and B₂O₃

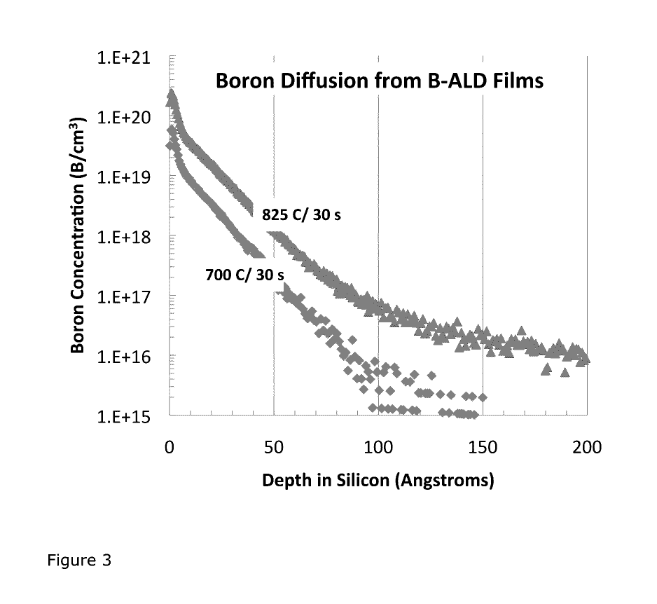

The BₓAl₂₋ₓO₃ layered films were annealed under N₂ ambient for 30 sec at 700° C., 825° C. and 950° C. The samples were then stripped of the BₓAl₂₋ₓO₃ films and measured for the boron/cm³ concentration in the underlying silicon using Secondary Ion Mass Spectroscopy (SIMS). The results for the 825° C., 30 sec anneal are shown in FIG. 3. Assuming a background concentration of 5E16, the junction depth is 100 A and the surface concentration is ˜2E20, close to the boron solubility limit in silicon. Assuming the diffusion follows a random walk process ˜sq root of time), we would have a ˜20 A junction using a 1 second Rapid Thermal Anneal (RTA) at 825° C., while maintaining the high surface concentration.

The choice of dopant precursors includes halides of both boron and phosphorus. The use of the halide B₂F₄ is not unique. It is expected that several halides of boron may be used, e.g. BF₃, BCl₃, BBr₃, B₂Cl₄, or B₂Br₃ as well as organic precursors. Likewise, the choice of phosphorus precursors may include PF₃, PF₅, PCl₃, PCl₅, PBr₃, and PBr₅, as well as organic precursors.

Density functional theory indicates the feasibility of producing elemental phosphorus ALD films from the PF₃ (or PCl₃ or PBr₃)-silane replacement reaction. (Ref9 Goldberg). Hence in the phosphorus case, we have the option to incorporate elemental phosphorus with a compatible oxide, which may increase the dopant incorporation efficiency of the process. Elemental phosphorus has sublimation vapor pressures of 10 0Pa at 350° -530° C., so while elemental phosphorus may be made by ALD at lower temperatures, e.g. 250° C., elemental phosphorus would need to be placed in a stable matrix oxide for use as a diffusion source. However phosphorus oxide by itself sublimes at 360° C. One possibility is to use thermally stable Al₂O₃ as a matrix host. Even though aluminum is an acceptor in silicon, if present in the form of Al₂O₃, it is expected not to dissociate at practical diffusion temperatures (such as 850° C.) and would allow preferential diffusion of phosphorus from the mixture of PₓO_{y} and Al₂O₃. Other higher temperature stable oxides or nitrides are needed for a matrix to incorporate the phosphorus and particular phosphorus silicate glass has been used for gettering layer applications, so mixtures of PₓO_{y} and SiO₂ or SiN may be useful. In conclusion, however, a preferred embodiment is to use a replacement ALD chemistry process (Phoshorus-halide/Si₂H₆) to deposit elemental phosphorus using a phosphorus halide precursor and a silane precursor to deposit elemental phosphorus layered within an Al₂O₃ matrix, said phosphorus and Al₂O₃ being made using a sequential ALD process.

The possibility also exits to modify the silicon surface by introducing, for example Ge into the silicon to increase the solubility on the diffusing boron, or carbon of other material modifying properties. A diffused dopant may also be applied to germanium substrates or SiGe alloy substrates.

What is claimed is:

1. A conformal thermal ALD film comprising a combination of elements and containing a dopant in intimate contact with a semiconductor substrate, said combination having stable ambient and thermal annealing properties providing a shallow diffused dopant profile into the semiconductor substrate.

2. An process comprising depositing a boron containing film using B₂F₄—H₂O sequenced in turn with TMA—H₂O, producing a BₓAl₂₋ₓO₃ layered film.

3. An process comprising depositing a phosphorus containing film using one of: a phosphorus halide precursor and a silane precursor producing elemental phosphorus material layered within an ALD oxide or nitride matrix, or alternately, a phosphorus halide with an oxidant to produce phosphorus oxide material layered within a ALD oxide or nitride matrix.
